(19) United States
(12) Patent Application Publication
(10) Pub. No.: US 2026/0173985 A1
(43) Pub. Date: Jun. 18, 2026

(54) PLATED PACKAGING FOR A SEMICONDUCTOR CHIP

(71) Applicant: Shengmin Wen, Phoenix, AZ (US)

(72) Inventor: Shengmin Wen, Phoenix, AZ (US)

(21) Appl. No.: 19/420,703

(22) Filed: Dec. 15, 2025

Related U.S. Application Data
(60) Provisional application No. 63/734,388, filed on Dec. 16, 2024.

(51) Int. Cl. H10W 90/00; H10W 70/40; H10W 74/10

(52) U.S. Cl. CPC H10W 90/766; H10W 70/417; H10W 70/429; H10W 74/111

(57) ABSTRACT

A module includes a semiconductor chip having at least a first terminal contact surface and a second terminal contact surface on its top surface. A large shape copper (Cu) layer is plated to connect the first terminal contact surfaces and the external terminals, and a Cu trace is plated to connect the second terminal contact surface and the external terminals.

### CROSS-REFERENCE TO RELATED APPLICATIONS

This application claims the benefit of U.S. Provisional Patent Application No. 63/734,388 filed on Dec. 16, 2024, which is incorporated by reference herein.

### BACKGROUND

### Technical Field

The disclosed embodiments relate to a module comprising a semiconductor chip and in various embodiments to a packaging technique for electrically connecting the semiconductor chip to the external terminals of the module.

### Related Art

Various techniques are available to electrically connect a power semiconductor chip in a module to external terminals of the module. For example, clip-bonding, ribbon-bonding or wire-bonding using Al, Cu or Au are techniques known in the art. In the field of electrical vehicles and clean energy applications, power semiconductor chips operate at high voltage, high current and high temperature conditions. These bonding techniques result in fast degradation at the bonding interfaces due to thermal-mechanical fatigue. A connecting method providing more reliability over time under such harsh condition is needed.

### BRIEF DESCRIPTION OF THE DRAWINGS

Aspects of the disclosed embodiments are made more evident by way of example in the following detailed description of embodiments when read in conjunction with the attached drawing figures, wherein:

FIG. 1A is perspective view of an embodiment of a module that uses Cu-clip and wire bond (without showing the molding compound for clarity).

FIG. 1B is cross sectional view along plane A-A shown in FIG. 1A that uses Cu-clip and wire bond with the molding compound shown.

FIG. 2 is a simplified top view of this module without the top protect layer, without molding, and without portion of the bottom lead frame so that the connecting method can be clearly seen and understood.

FIG. 3 is a cross sectional view of an embodiment.

FIG. 4 is a cross sectional view of another embodiment.

FIG. 5 is a cross sectional view of yet another embodiment.

FIG. 6 is a cross sectional view of yet another embodiment.

FIG. 7 depicts an example process flow for forming a power semiconductor chip connection in a module.

FIG. 8 depicts another example process flow for forming a power semiconductor chip connection in a module.

FIG. 9 depicts yet another example process flow for forming a power semiconductor chip connection in a module.

FIG. 10 depicts yet another example process flow for forming a power semiconductor chip connection in a module.

FIG. 11 is an embodiment of a module including a bonded wire.

FIG. 12 is a cross sectional view of an embodiment.

FIG. 13 depicts an example process flow for forming a power semiconductor chip connection in a module.

### DETAILED DESCRIPTION

Modules described in the following comprise at least one electronic component such as a semiconductor chip. The electronic component can be a power semiconductor chip or a chip operating in the standard power (i.e., non-power) regime, e.g., a logic integrated circuit or a sensor chip, e.g., a CCD (charge coupled device) or for instance a MEMS (micro-electronical mechanical structure) such as a pressure sensor etc.

A power semiconductor chip may have a power consumption that spans over a wide range, starting from about one or several amperes and about five or more volts to several hundreds of amperes or several hundreds of volts. For example, a power semiconductor chip may be a MOSFET (Metal Oxide Semiconductor Field Effect Transistor), JFET (Junction Field Effect Transistor), IGBT (Insulated-Gate Bipolar Transistor), BJT (Bipolar Junction Transistor) or thyristor.

The semiconductor chip may be a vertical semiconductor device or a horizontal semiconductor device. A vertical semiconductor device has a top face with a first contact surface defining a first current carrying electrode and a bottom face with a second contact surface defining a second current carrying electrode. The load current flows in a vertical direction between the top contact surface and the bottom contact surface. The top face in general also has at least one more additional contact surface, e.g., one that defines a gate control electrode. In contrast thereto, in a lateral semiconductor device, both load current contact surfaces are arranged on the top face of the semiconductor chip.

The module may be packaged, i.e., may comprise a mold compound. The mold compound may, for example, be made of a thermoplastic resin or a thermosetting plastic, for example epoxy resin. It typically encapsulates one or more chips of the module. A backside of a carrier on which the chip or the chips are mounted may either be over-molded by the mold compound or may remain exposed. It is also possible that the chip carrier(s) or the chip(s) are connected to a heat sink which remains at least partially uncovered by the mold material.

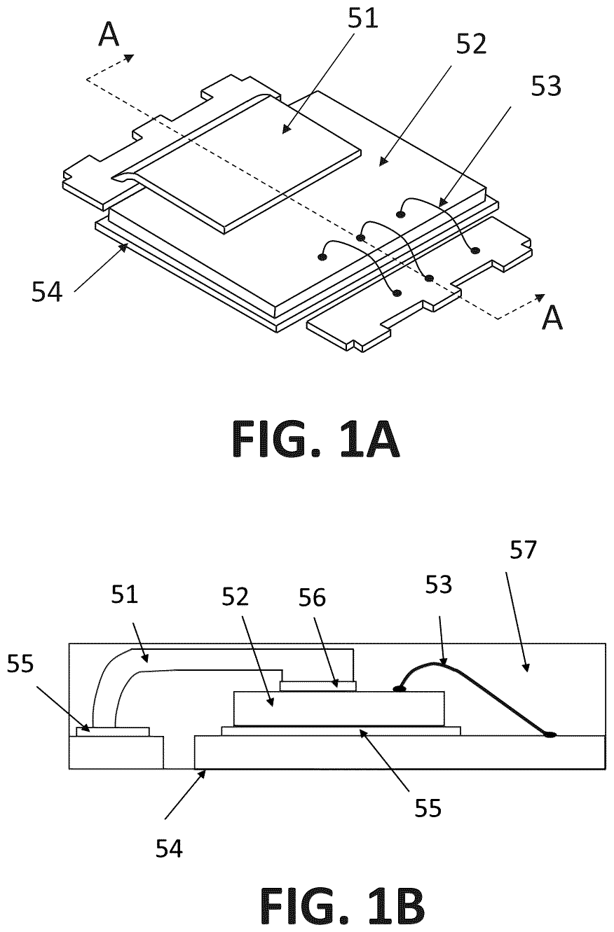

FIGS. 1A-1B shows a perspective view and cross-sectional view respectively of a power module comprising a semiconductor chip with connecting methods that use Cu clip 51 and wire bond 53. Cu clip 51 provides connecting with one end being soldered onto the top connect surface of chip 52 and the other end being soldered to the lead frame 54. Solder connections 55 and 56 become degraded because the brittle intermetallic layers formed between the Cu clip 51 and the solder layer 56 and 56 under high temperature cyclic loading in the normal usage condition are prone to failure. In addition, the Cu clip 51 itself becomes hardened to cause the semiconductor chip to crack. Mold compound 57 seals the whole structure.

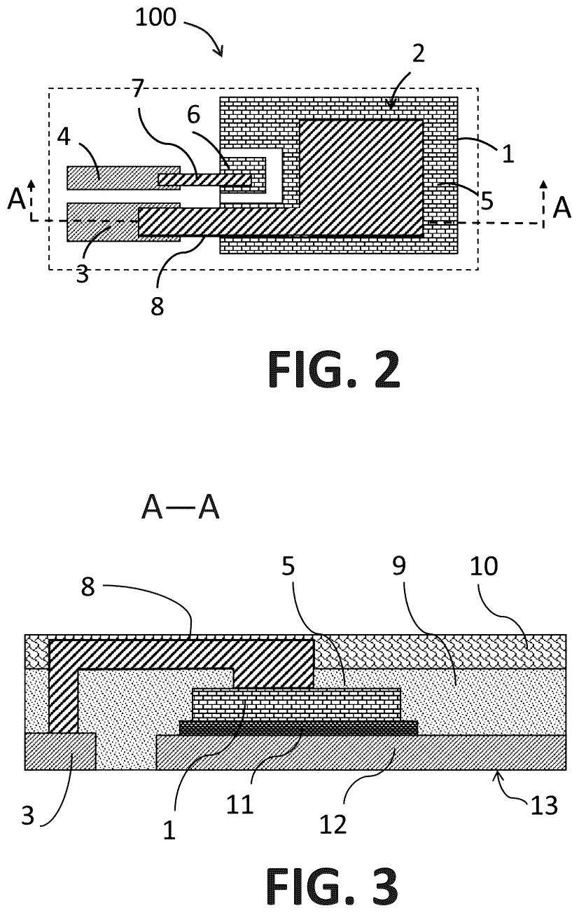

FIG. 2 shows a planar view of a module 100 comprising a semiconductor chip 1 having a top surface 2 and leads 3, 4 which may represent external terminals for electrically connecting the semiconductor chip 1 to an external assembly, for instance a circuit board or another mounting platform on which the module is to be mounted. The top surface 2 of the semiconductor chip 1 comprises two conductive contact surfaces 5, 6. The contact surfaces 5, 6 are insulated from each other. Typically, the smaller surface 6 is for control signal such as gate electrode and the bigger surface 5 is for high voltage and high current working load, e.g., the drain or source electrode of a power transistor implemented in the semiconductor chip 1. The contact surface 5 of the semiconductor chip 1 is interconnected to lead 3 by a big plated Cu shape 8. The contact surface 6 of the semiconductor chip 1 is interconnected to lead 4 by a plated trace 7. To clearly demonstrate the structure, this figure does not show the top layer, molding, and the bottom portion of the lead frame.

FIG. 3 shows a cross-sectional view of the module of FIG. 2 through line A-A. The contact surface 5 of the semiconductor chip 1 is interconnected to lead 3 by a thick plated Cu shape 8. In one embodiment, the Cu shape 8 has a thickness of more than 50 μm. In other embodiments, the Cu shape 8 has a thickness of 20 μm-50 μm. In other embodiments, the Cu shape may be thicker or thinner per designed power level requirement. The contact surface 6 of the semiconductor chip 1 is interconnected to lead 4 by a plated trace 7 which is not shown here. The connecting Cu shape 8 is built through electrolytic plating Cu on the surface area of lead 3 and contact surface 5 of the semiconductor chip 1. Here the chip 1 is attached to the external lead 12 through die attach layer 11 (through solder or conductive adhesive, e.g., Ag based sintering materials, soft solder, or through hybrid bonding), encapsulated with mold compound 9. After encapsulation, laser drill process is used to drill through the molding compound, to open and expose both the connecting surfaces on the leads and the contact surfaces of the chip, and electrolytic Cu plating process is used to build the connecting trace 7 or shape 8. Once the connecting is completed to the desired width and thickness, a final top layer 10 is laminated to seal and protect the plated trace 7 and shape 8. Detailed process steps of exemplary embodiments will be explained later.

In FIG. 3 the lead frame 13 is a structured sheet of metal, for instance Cu. This structured sheet of metal further comprises a lead 3, a lead 4 and a lead 12 forming an integral extension of the chip attach surfaces or die pad.

The semiconductor chip 1 may be a vertical p-type power transistor. In this case, the die pad on lead 12 is connected to the drain (D) contact area of the transistor, as the drain (D) contact area is located at the bottom face of the semiconductor chip 1. The top face of the semiconductor chip 1 carries a source(S) contact area 5 and a gate (G) contact area 6. The source contact area 5 is interconnected to the lead 3 by a plated thick Cu shape 8 and the gate contact area 6 is interconnected to the lead 4 by a plated Cu trace 7. Leads 3, 4, 12 may serve as external terminals of the module. Leads 3, 4, 12 may stick out of the molded package body and will be cut-off at a final singulation stage of the manufacturing process such that leads 3, 4, 12 will be insulated from each other in the finished module.

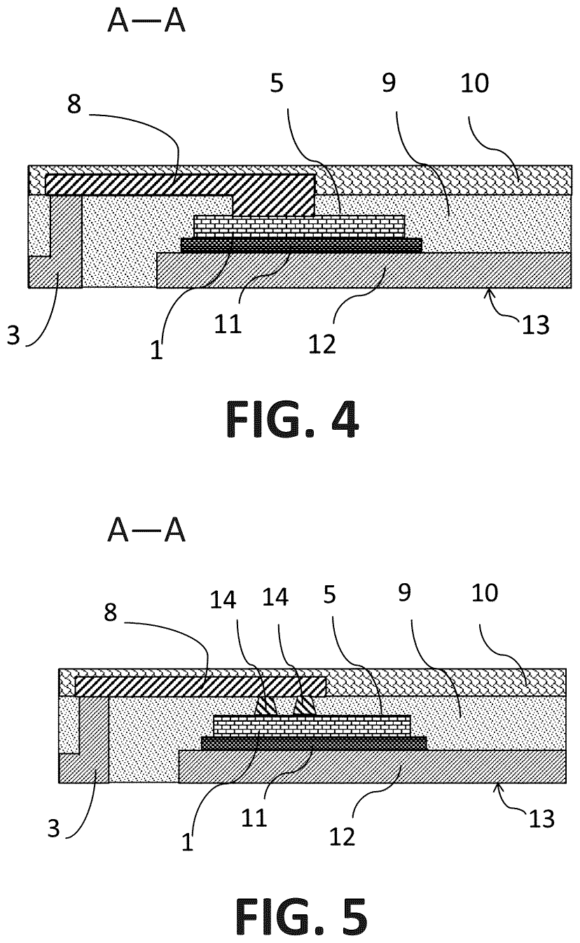

FIG. 4 shows a module that differs from the module shown in FIG. 3 mainly in that the leads 3 and 4 are bent upwards out of plane at such a height that they are exposed after molding and grinding. The embodiment of FIG. 4 may have the same planar view as shown in FIG. 2. Therefore there is no need to use laser drill to expose them for the plating of Cu trace 7 and Cu shape 8 to make the connections. Leads 3 and 4 may comprise Cu in some embodiments, but may have a different composition than trace 7 and Cu shape 8.

FIG. 5 shows a module that differs from the module shown in FIG. 4 mainly in that the semiconductor chip 1 is pre-bumped with bumps 14 on the contact areas 5 and 6 such that these bumps are exposed after molding and grinding therefore the plating of Cu trace 7 and Cu shape 8 to make the connecting can be completed without the need of laser drill through the molding to expose the contact areas 5 and 6. It is to be noted that bumps 14 can be a wire bond stud, or plated Cu bumps. In a planar view, the bumps 14 can be circular, oval, or other geometry.

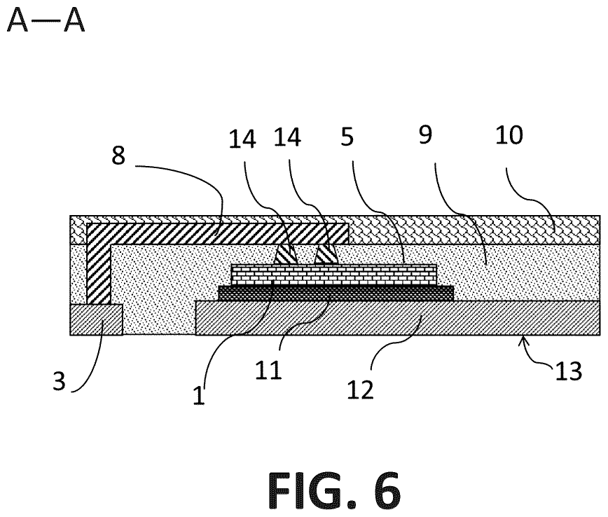

FIG. 6 shows a module that differs from the module shown in FIG. 3 mainly in that the semiconductor chip 1 is pre-bumped with bumps 14 on the contact areas 5 and 6 such that these bumps are exposed after molding and grinding therefore the plating of Cu trace 7 and Cu shape 8 to make the connecting can be completed without the need of laser drill through the molding to expose the contact areas 5 and 6. It is to be noted that bumps 14 can be a wire bond stud, or plated SnAg, or Cu bumps.

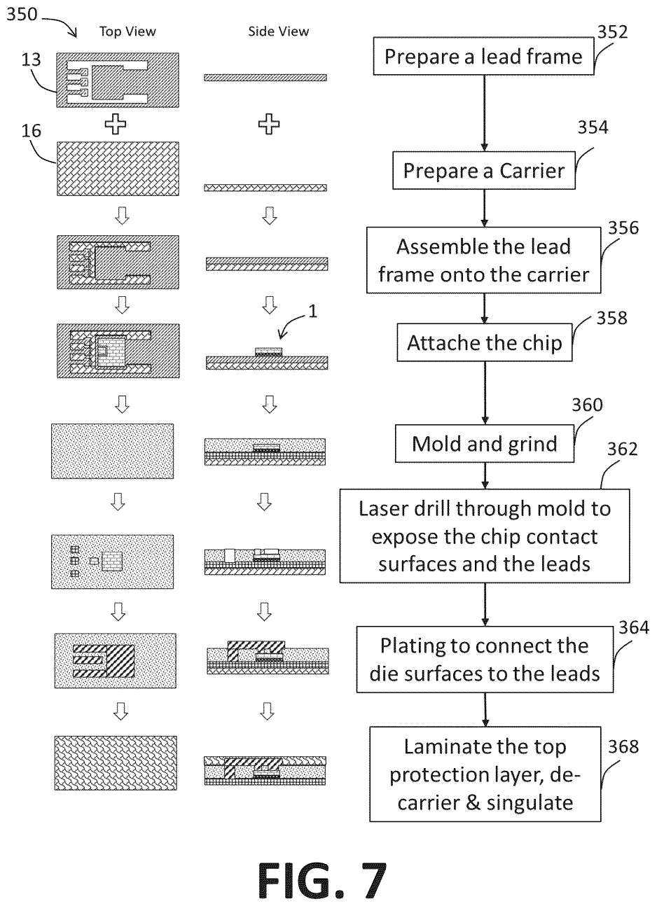

FIG. 7 depicts an example process flow 350 for making the module 100 shown in FIG. 3 (which has a planar view as shown in FIG. 2), according to some embodiments. In the example shown in FIGS. 2-3, the module is formed by connecting the chip contact areas and the leads contact areas with plated Cu shape and Cu trace, with FIG. 3 depicting the connecting configurations. As shown in FIG. 7, at steps 352 and 354, a patterned lead frame 13 and a carrier 16 are properly prepared. The lead frame is either formatted through a metal sheet (Cu or Al) or pattern plated. At step 356, the lead frame is attached onto the carrier. The attachment mechanism is temporary as at the last stage of process the lead frame is detached from the carrier. At step 358, the chip 1 is attached onto the lead frame 13 with the chip's contact areas facing up or facing away from the lead frame. Attachment of the chip 1 may be accomplished using a surface mount technology (SMT) process with solder. The attachment may also be a non-SMT process with adhesive, or a sintering process with Ag based sintering materials, or a hybrid bonding process that the bottom surface of the chip being directly bonded to the top surface of the lead frame without any bonding materials in between these two surfaces. At step 360, a mold compound layer is formed around and over the chip 1 and the leads of the lead frame. This may be achieved using a compression molding process, and the molding layer may be ground down. In FIG. 3, the mold compound layer is ground down to leave behind a portion of the mold compound layer in an area overlapping the chip 1; however, in various embodiments it is possible to grind the mold compound layer down further to expose the top surface of the chip 1 and remove this portion of the mold compound. At step 362, the portions of molding layer above the chip's contact surfaces and the connecting landing surfaces on top of the leads are removed to expose the chip contact surfaces and the leads' contact surfaces, preparing them for Cu plating. The removal process may be a laser ablation process. At step 364, Cu plating process is used to plate a large and thick Cu layer shape and trace accordingly per the chip's contact surfaces, making robust and reliably connections between the contact surfaces in the chip surface and the leads. At step 368, the plated Cu shapes and traces are sealed with a film or other top layer to provide electrical insulation among the plated Cu shape and trace and environmental protection. The top layer may be a dielectric layer such as prepreg. At this stage also the carrier is removed from the bottom side of the lead frame. It is noted that lead frame process usually is in strip format with many units on the strip. This stage may involve singulating the lead frame strip into a plurality of individual units. The singulation also cuts the connections among the leads so that the leads are insulated from each other. A highly reliable power module may be achieved.

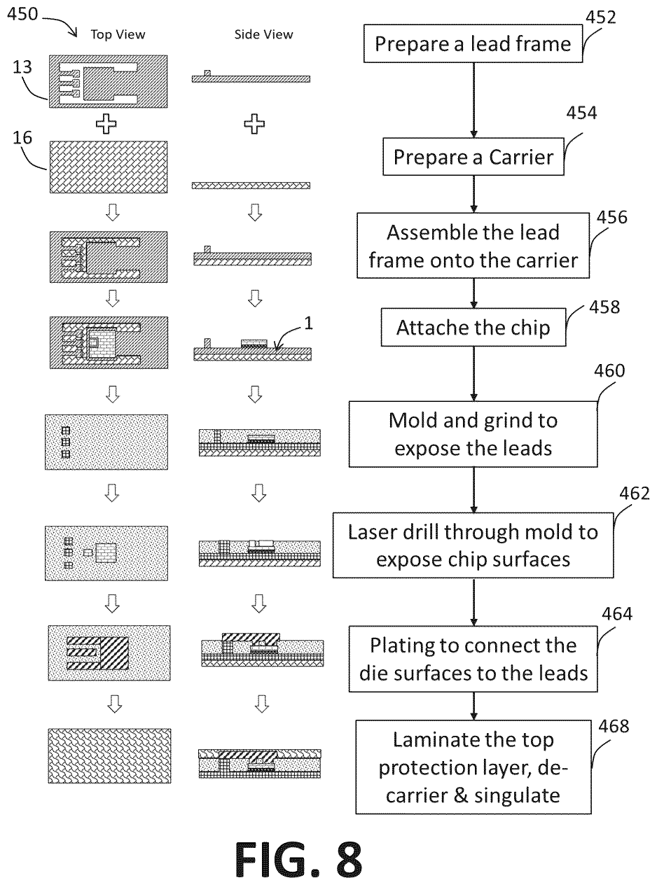

FIG. 8 depicts an example process flow 450 for making an embodiment of the module 100 of FIG. 4, (which has the planar view of FIG. 2) according to some embodiments. In the example shown in FIG. 2 and FIG. 4, the module is formed by connecting the chip contact surfaces and the leads contact surfaces with plated Cu shape and Cu trace, with FIG. 4 depicting the connecting configurations. As shown in FIG. 8, at steps 452 and 454, a patterned lead frame 13 and a carrier 16 are properly prepared. The lead frame is either formatted through a metal sheet (Cu or Al) or pattern plated. In this configuration, the lead frame differs from that used in FIG. 7 in that lead frame 13 has the connecting ends of leads bent upright to an out-of-plane with such a height that the ends of the leads may be exposed after mold grinding in later steps. At step 456, the lead frame is attached onto the carrier. The attachment mechanism is temporary as at the last stage of process the lead frame is detached from the carrier. At step 458, the chip 1 is attached onto the lead frame 13 with the chip's contact surfaces facing up or facing away from the lead frame. Attachment of the chip 1 may be accomplished using a surface mount technology (SMT) process with solder. The attachment may also be a non-SMT process with adhesive, or a sintering process with Ag based sintering materials, or a hybrid bonding process that the bottom surface of the chip being directly bonded to the top surface of the lead frame without any bonding materials in between these two surfaces. At step 460, a mold compound layer is formed around and over the chip 1 and the leads of the lead frame. This may be achieved using a compression molding process, and the molding layer may be ground down to expose the connection ends of the leads while at the same time leave behind a portion of the mold compound layer in an area overlapping the chip 1; however, in various embodiments it is possible to grind the mold compound layer down further to expose the top surface of the chip 1 and remove this portion of the mold compound. At step 462, the portions of molding layer above the chip's contact surfaces are removed to expose the chip contact surfaces, preparing them for Cu plating. The removal process may be a laser ablation process. At step 464, Cu plating process is used to plate a large and thick Cu layer shape and trace accordingly per the chip's contact surfaces, making robust and reliably connections between the contact surfaces in the chip surface and the ends of the leads. At step 468, the plated Cu shapes and traces are sealed with a film or other top layer to provide electrical insulation among the plated Cu shape and trace and environmental protection. The top layer may be a dielectric layer such as prepreg. At this stage also the carrier is removed from the bottom side of the lead frame. It is noted that lead frame process usually is in strip format with many units on the strip. This stage may involve singulating the lead frame strip into a plurality of individual units. The singulation also cuts the connections among the leads so that the leads are insulated from each other. A highly reliable power module may be achieved.

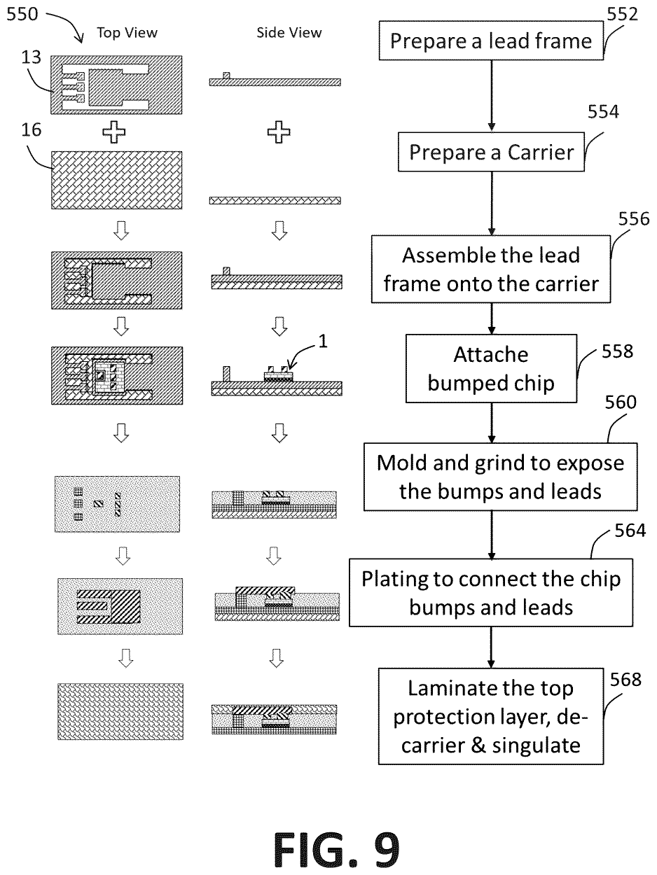

FIG. 9 depicts an example process flow 550 for making the module 100 shown in FIG. 5 (which has the planar view of FIG. 2), according to some embodiments. In the example shown in FIG. 2 and FIG. 5, the module is formed by connecting the chip contact surfaces and the leads contact surfaces with plated Cu shape and Cu trace, with FIG. 5 depicting the connecting configurations.

As shown in FIG. 9, at steps 552 and 554, a patterned lead frame 13 and a carrier 16 are properly prepared. The lead frame is either formatted through a metal sheet (Cu or Al) or pattern plated. In this configuration, the lead frame differs from that used in FIG. 7 in that lead frame 13 has the connecting ends of leads bent upright to an out-of-plane with such a height that the ends of the leads may be exposed after mold grinding in the later steps. At step 556, the lead frame is attached onto the carrier. The attachment mechanism is temporary as at the last stage of process the lead frame is detached from the carrier. At step 558, a chip 1 with bumps 14 on its contact surfaces is attached onto the lead frame 13 with the chip's contact surfaces facing up or facing away from the lead frame. Attachment of the chip 1 may be accomplished using a surface mount technology (SMT) process with solder. The attachment may also be a non-SMT process with adhesive, or a sintering process with Ag based sintering materials, or a hybrid bonding process that the bottom surface of the chip being directly bonded to the top surface of the lead frame without any bonding materials in between these two surfaces. At step 560, a mold compound layer is formed around and over the chip 1 and the leads of the lead frame. This may be achieved using a compression molding process, and the molding layer may be ground down to expose the connection ends of the leads and the bumps that are connected to the contact surfaces of the chip 1 while at the same time keep the mold compound layer cover the top surface the chip 1. At step 564, Cu plating process is used to plate a large and thick Cu layer shape and trace accordingly per the chip's contact surfaces, making robust and reliably connections between the bumps on the ship contact surfaces in the chip surface and the ends of the leads. At step 568, the plated Cu shapes and traces are sealed with a film or other top layer to provide electrical insulation among the plated Cu shape and trace and environmental protection. The top layer may be a dielectric layer such as prepreg. At this stage also the carrier is removed from the bottom side of the lead frame. It is noted that lead frame process usually is in strip format with many units on the strip. This stage may involve singulating the lead frame strip into a plurality of individual units. The singulation also cuts the connections among the leads so that the leads are insulated from each other. A highly reliable power module may be achieved. It is noted that this process flow may be the lowest cost process flow due to the elimination of laser ablation steps to expose the contact surfaces of the chip and the leads.

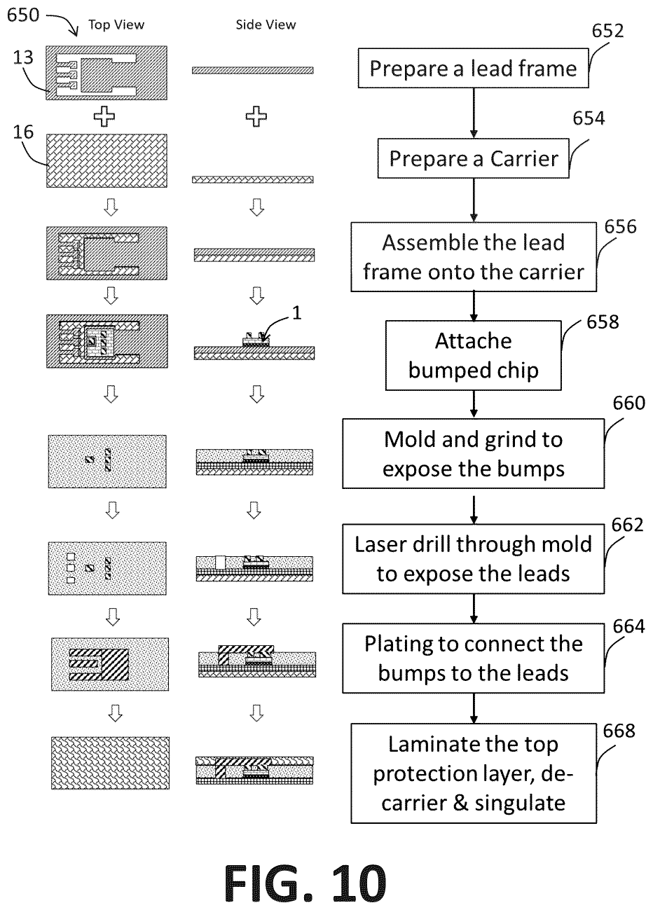

FIG. 10 depicts an example process flow 650 for making the module 100 shown in FIG. 6 (which has the planar view of FIG. 2), according to some embodiments. In the example shown in FIG. 2 and FIG. 6, the module is formed by connecting the chip contact surfaces and the leads contact surfaces with plated Cu shape and Cu trace, with FIG. 6 depicting the connecting configurations.

As shown in FIG. 10, at steps 652 and 654, a patterned lead frame 13 and a carrier 16 are properly prepared. The lead frame is either formatted through a metal sheet (Cu or Al) or pattern plated. At step 656, the lead frame is attached onto the carrier. The attachment mechanism is temporary as at the last stage of process the lead frame is detached from the carrier. At step 658, a chip 1 with bumps 14 on its contact surfaces is attached onto the lead frame 13 with the chip's contact surfaces facing up or facing away from the lead frame.

Attachment of the chip 1 may be accomplished using a surface mount technology (SMT) process with solder. The attachment may also be a non-SMT process with adhesive, or a sintering process with Ag based sintering materials, or a hybrid bonding process that the bottom surface of the chip being directly bonded to the top surface of the lead frame without any bonding materials in between these two surfaces. At step 660, a mold compound layer is formed around and over the chip 1 and the leads of the lead frame. This may be achieved using a compression molding process, and the molding layer may be ground down to expose the bumps 14 that are connected to the contact surfaces of the chip 1 while at the same time keep the mold compound layer cover the top surface the chip 1. At step 662, the portions of molding layer above the contact surfaces of the leads are removed to expose the contact surfaces, preparing them for Cu plating. The removal process may be a laser ablation process. At step 664, Cu plating process is used to plate a large and thick Cu layer shape and trace accordingly per the chip's contact surfaces, making robust and reliably connections between the bumps on the chip surface and the ends of the leads. At step 668, the plated Cu shapes and traces are sealed with a film or other top layer to provide electrical insulation among the plated Cu shape and trace and environmental protection. The top layer may be a dielectric layer such as prepreg. At this stage also the carrier is removed from the bottom side of the lead frame. It is noted that lead frame process usually is in strip format with many units on the strip. This stage may involve singulating the lead frame strip into a plurality of individual units. The singulation also cuts the connections among the leads so that the leads are insulated from each other. A highly reliable power module may be achieved.

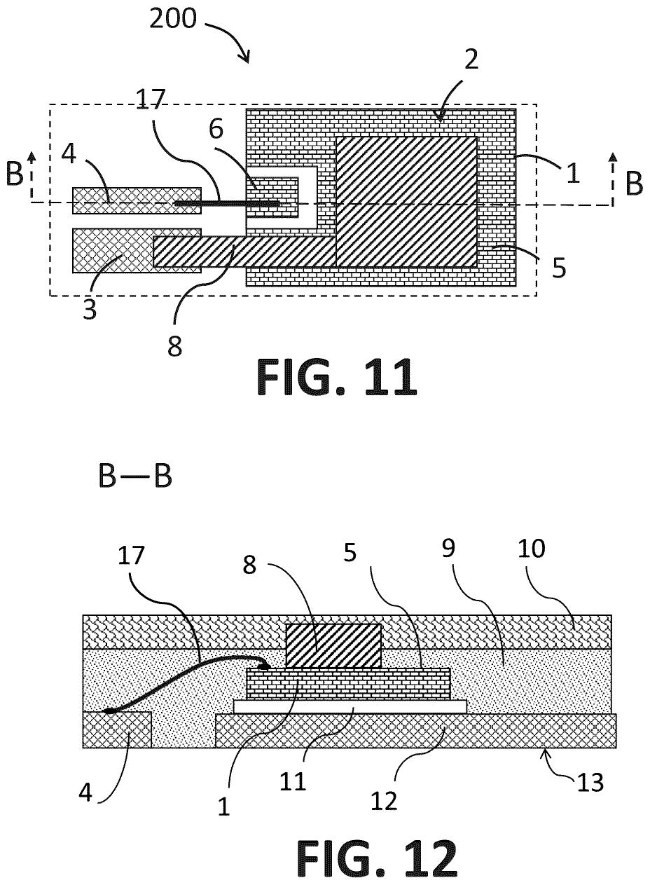

FIG. 11 shows another embodiment module 200 comprising a semiconductor chip 1. The embodiment is identical to module 100 depicted in FIG. 2 except trace 7 in FIG. 2 is replaced with a bonded wire 17. The bonding wire may be a Cu wire or an Au wire.

FIG. 12 shows a cross-sectional view of the module of FIG. 11 through line B-B. The terminal contact surface 6 of the semiconductor chip 1 is interconnected to a contact surface of lead 4 through a bonded wire. The terminal contact surface 5 of the semiconductor chip 1 is interconnected to lead 3 by a big and thick plated Cu shape 8 which is partially shown here.

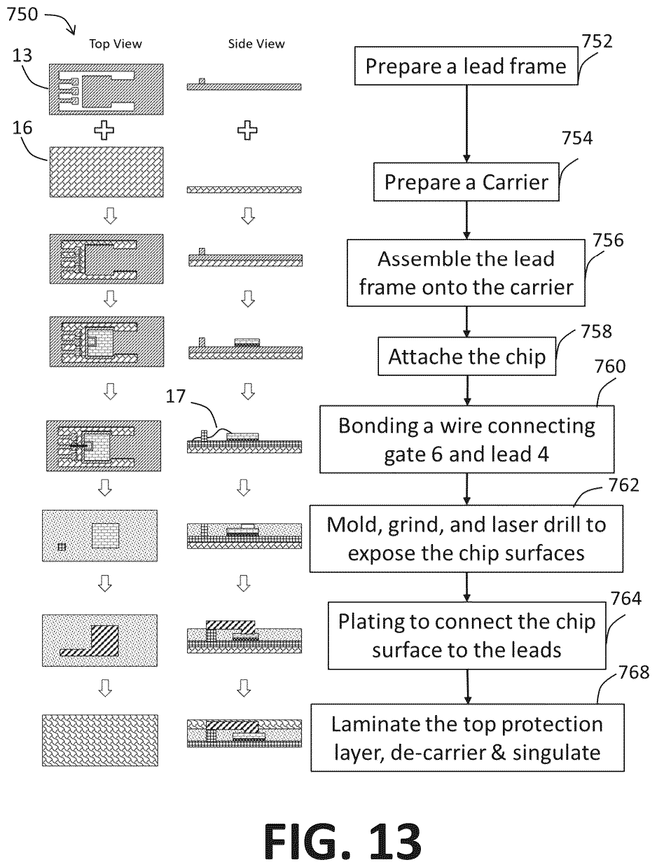

FIG. 13 depicts an example process flow 750 for making the module 200 shown in FIG. 11 with configuration of FIG. 12, according to some embodiments. In the example shown in FIG. 11 and FIG. 12, the module is formed by connecting the chip contact surfaces and the leads contact surfaces with plated Cu shape and a bond wire, with FIG. 12 depicting the connecting configurations. As shown in FIG. 13, at steps 752 and 754, a patterned lead frame 13 and a carrier 16 are properly prepared. The lead frame is either formatted through a metal sheet (Cu or Al) or pattern plated, and the lead that connects to the chip contact surface 5 is bent out-of-plane with such a height that the ends of the leads may be exposed after mold grinding in the later steps. At step 756, the lead frame is attached onto the carrier 16. The attachment mechanism is temporary as at the last stage of process the lead frame is detached from the carrier. At step 758, a chip 1 is attached onto the lead frame 13 with the chip's contact surfaces facing up or facing away from the lead frame. Attachment of the chip 1 may be accomplished using a surface mount technology (SMT) process with solder. The attachment may also be a non-SMT process with adhesive, or a sintering process with Ag based sintering materials, or a hybrid bonding process that the bottom surface of the chip being directly bonded to the top surface of the lead frame without any bonding materials in between these two surfaces. At step 760, a wire is bonded to the chip terminal contact surface 6 and the contact surface of lead 4, making the connection between the chip and the external lead. At step 762, mold compound layer is formed around and over the chip 1 and the leads of the lead frame. This may be achieved using a compression molding process, and the molding layer may be ground down to expose the lead 3, the portions of molding layer above the chip contact surface 5 are removed to expose the chip contact surfaces, preparing for thick Cu shape plating. The removal process may be a laser ablation process. At step 764, Cu plating process is used to plate a large and thick Cu layer shape, making robust and reliably connections between the chip surface and the end of the leads. At step 768, the plated Cu shape is sealed with a film or other top layer to provide electrical insulation and environmental protection. The top layer may be a dielectric layer such as prepreg. At this stage also the carrier is removed from the bottom side of the lead frame. It is noted that lead frame process usually is in strip format with many units on the strip. This stage may involve singulating the lead frame strip into a plurality of individual units. The singulation also cuts the connections among the leads so that the leads are insulated from each other. A highly reliable power module may be achieved.

While the above embodiments have been described with reference to power semiconductor module, the connecting technology described above may be used to form other semiconductor modules where high voltage, high current density, or high temperature application environment is desired.

Thus, the embodiments and examples set forth herein are presented in order to best explain the present invention and its particular application and to thereby enable those skilled in the art to make and use the invention. However, those skilled in the art will recognize that the foregoing description and examples have been presented for the purposes of illustration and example only. The description as set forth is not intended to be exhaustive or to limit the invention to the precise form disclosed.

What is claimed is:

1. A semiconductor device comprising:
a lead frame comprising a die pad and plurality of leads including at least a first lead and a second lead;
a semiconductor chip mounted on the lead frame, the semiconductor chip having a first terminal contact surface, a second terminal contact surface, and a third terminal contact surface, wherein the third terminal contact surface electrically connects to the lead frame via the die pad;
a molding compound partially encapsulating the semiconductor chip and the lead frame;
a Cu shape plated at least partially over the molding compound that connects the first terminal contact surface of the semiconductor chip to the first lead of the lead frame; and
a connecting element that connects the second terminal contact surface of the semiconductor chip to the second lead of the lead frame.

2. The semiconductor device of claim 1, wherein the third terminal contact surface of the semiconductor chip is on an opposite surface of the semiconductor chip relative to the first and second terminal contact surfaces.

3. The semiconductor device of claim 1, wherein the semiconductor chip comprises a power transistor chip, wherein the first terminal contact surface comprises a source, the second terminal contact surface comprises a gate, and the third terminal contact surface comprises a drain.

4. The semiconductor device of claim 1, further comprising:
a lamination layer over the Cu shape.

5. The semiconductor device of claim 1, wherein the connecting element comprises:
a Cu trace plated at least partially over the molding compound that connects the second terminal contact surface of the semiconductor chip to the second lead of the lead frame.

6. The semiconductor device of claim 5, wherein the lead frame comprises a planar metal sheet, and wherein the Cu shape and the Cu trace each extend through holes in the molding compound to couple to the first and second leads respectively.

7. The semiconductor device of claim 5, wherein first and second leads of the lead frame include bent portions that are bent out of plane relative to a planar portion of the lead frame such that ends of the bent portions are exposed through the molding compound, and wherein the Cu shape and the Cu trace couple to the ends of first and second leads respectively over the molding compound.

8. The semiconductor device of claim 5, wherein the Cu shape and the Cu trace extend through the molding compound in a region over the semiconductor chip to electrically couple with the first terminal contact surface and the second terminal contact surface respectively.

9. The semiconductor device of claim 5, further comprising:
at least a first bump on the first terminal contact surface of the semiconductor chip that is exposed through the molding compound and electrically couples with the Cu shape; and
at least a second bump on the second terminal contact surface of the semiconductor chip that is exposed through the molding compound and electrically couples with the Cu trace.

10. The semiconductor of claim 1, wherein the connecting element comprises:
a wire through the molding compound that is wire bonded to the second terminal contact surface of the semiconductor chip and to the second lead.

11. The semiconductor of claim 1, wherein the Cu shape has a thickness of at least 20 micrometers.

12. The semiconductor of claim 1, wherein the Cu shape has a thickness of at least 50 micrometers.

13. A power transistor module comprising:
a lead frame comprising a die pad for a drain connection, a source lead, and a gate lead;
a power transistor chip mounted on the lead frame, the power transistor chip having a source terminal, a gate terminal, and a drain terminal, wherein the drain terminal electrically connects to the drain lead via the die pad;
a molding compound partially encapsulating the power transistor chip and the lead frame;
a Cu shape plated at least partially over the molding compound that connects the source terminal of the power transistor chip to the source lead of the lead frame; and
a Cu trace plated at least partially over the molding compound that connects the gate terminal of the power transistor chip to the gate lead of the lead frame.

14. A method for manufacturing a semiconductor device, the method comprising:
mounting a semiconductor chip on a lead frame, wherein the semiconductor chip has a first terminal contact surface, a second terminal contact surface and a third terminal contact surface, wherein the lead frame has a first lead with a first contact surface, a second lead with a second contact surface, and a die pad, and wherein the third terminal contact surface is electrically connected to the die pad;
encapsulating the semiconductor chip and the lead frame with molding compound;
grinding the molding compound to a planar surface;
plating over the molding compound, a Cu shape to connect the first terminal contact surface of the semiconductor chip and the first contact surface of the first lead of the lead frame; and
electrically connecting the second terminal contact surface of the semiconductor chip and the second contact surface of the second lead of the lead frame.

15. The method according to claim 14, wherein the semiconductor chip is a power transistor.

16. The method according to claim 14, wherein the lead frame comprises a planar metal sheet, the method further comprising:
after grinding and before plating, drilling through the molding compound to expose the first terminal contact surface and the second terminal contact surface of the semiconductor chip, and to expose the first contact surface of the first lead of the lead frame and the second contact surface of the second lead of the lead frame.

17. The method according to claim 14, wherein the lead frame comprises a planar portion, and wherein the first and second leads of the lead frame are bent out of plane relative to the planar portion such that the first and second leads are exposed after grinding, the method further comprising:
after grinding and before plating, drilling through the molding compound to expose the first terminal contact surface and the second terminal contact surface of the semiconductor chip.

18. The method of claim 14, wherein the semiconductor chip has electrically connected bumps on the first terminal contact surface and the second terminal contact surface, and wherein plating the Cu shape comprises plating the Cu shape to electrically connect with the bumps.

19. The method of claim 14, wherein electrically connecting the second terminal contact surface of the semiconductor chip and the second contact surface of the second lead of the lead frame comprises plating a Cu trace over the molding compound.

20. The method of claim 14, wherein electrically connecting the second terminal contact surface of the semiconductor chip and the second contact surface of the second lead of the lead frame comprises:
bonding a wire between the second terminal contact surface of the semiconductor chip and the second contact surface of the second lead of the lead frame.
